(19) United States
(12) Patent Application Publication
(10) Pub. No.: US 2025/0245395 A1
(43) Pub. Date: Jul. 31, 2025

(54) Determining Optimal Subsea Pipeline Routes based on a Geographic Information System

(71) Applicant: Saudi Arabian Oil Company, Dhahran (SA)

(72) Inventors: Wessam H. Mahmoud, Al-Khobar (SA); Hussain M. AlNasser, Safwa (SA); Mohammed Al-Sadiq, Al-Sadiq (SA); Ahmed Al-Khaiyat, Al-Khobar (SA); Abdullah Al-Zahrani, Al-Khobar (SA)

(21) Appl. No.: 18/422,824

(22) Filed: Jan. 25, 2024

(51) Int. Cl. G06F 30/18

(52) U.S. Cl. CPC G06F 30/18

(57) ABSTRACT

A computer implemented method that enables determination of optimal routes for subsea pipelines based on geographic information systems is described. The method includes obtaining geophysics data and constraints associated with an area and transforming the geophysics data and constraints, source nodes, and destination nodes into a cell-based geophysics model. The cell-based geophysics model is evaluated to create a composite cost surface corresponding to the area, and a scenario with least cost main routes and least cost lateral pipeline routes across interconnected main routes and lateral routes in the cell-based geophysics model is determined.

### TECHNICAL FIELD

This disclosure relates generally to determination of optimal routes for subsea pipelines based on geographic information systems.

### BACKGROUND

Geographic information systems store, visualize, analyze, and interpret geographic data. Geographic data is associated with a geographic location of features.

### BRIEF DESCRIPTION OF DRAWINGS

FIG. 1 shows a workflow that enables a GIS-based determination of optimal routes for subsea pipelines.

FIG. 2 shows pre-collected geophysical data.

FIG. 3 shows least cost routes between destination and source nodes based on a cost surface.

FIG. 4A shows a first scenario.

FIG. 4B shows a second scenario.

FIG. 5 shows metrics associated with proposed subsea routes.

FIG. 6 is a process flow diagram of a process that enables GIS-based determination of optimal routes for subsea pipelines.

FIG. 7 illustrates hydrocarbon production operations that include both one or more field operations and one or more computational operations, which exchange information and control exploration for the production of hydrocarbons.

FIG. 8 is a schematic illustration of an example controller (or control system) that enables a GIS-based determination of optimal routes for subsea pipelines.

### DETAILED DESCRIPTION

The use of Geographic Information System (GIS) spatial analysis tools enables pipeline route selection. During pipeline route selection, locations of a route through, along, or above the Earth's surface are determined. Traditionally, a least-cost path analysis (LCPA) locates a single pipeline route between two nodes in a nodal analysis of a pipeline network. However, traditional techniques fail to determine interconnected routes among multi-source and multi-destination nodes.

The present techniques enable a GIS-based workflow that determines optimal pipeline routes for interconnected subsea pipeline networks. The present techniques enable a determination of an optimal location of main and lateral pipeline routes that interconnect multi-source and multi-destination nodes of a pipeline network. In some embodiments, the optimal location minimizes installation costs of new subsea pipelines, maintains a safe installation process, complies with regulations put forth by regulatory bodies (e.g., Marine & Field Operations), expedites project workflows, or any combinations thereof.

Some advantages of the present techniques include an improvement to selection of pipeline routes, which is a first step in design and construction of new subsea pipelines in offshore projects. The improvement occurs by selecting optimal routes that minimize the cost, improve the schedule, and maintain the safety of an installation process. Traditional techniques to determine routes are time-consuming and include manually analyzing different maps, manually sketching several scenarios of the possible routes, and conducting multiple review meetings to agree on the final selection. This traditional method is not error-proof as there can still be some manually selected routes that fail to comply with the regulations put forth by regulatory bodies.

The present techniques minimize the construction cost of new subsea pipelines by determining pipeline routes associated with a least cost, and also minimize the construction risk of accidental pipeline leakage that may cause negative production and negative environmental impacts. Further, the present techniques expedite offshore project workflows by reducing the time consumed to select pipeline routes. The present techniques enable decision makers to select the optimal routes based on a quantifiable costs and risk assessments.

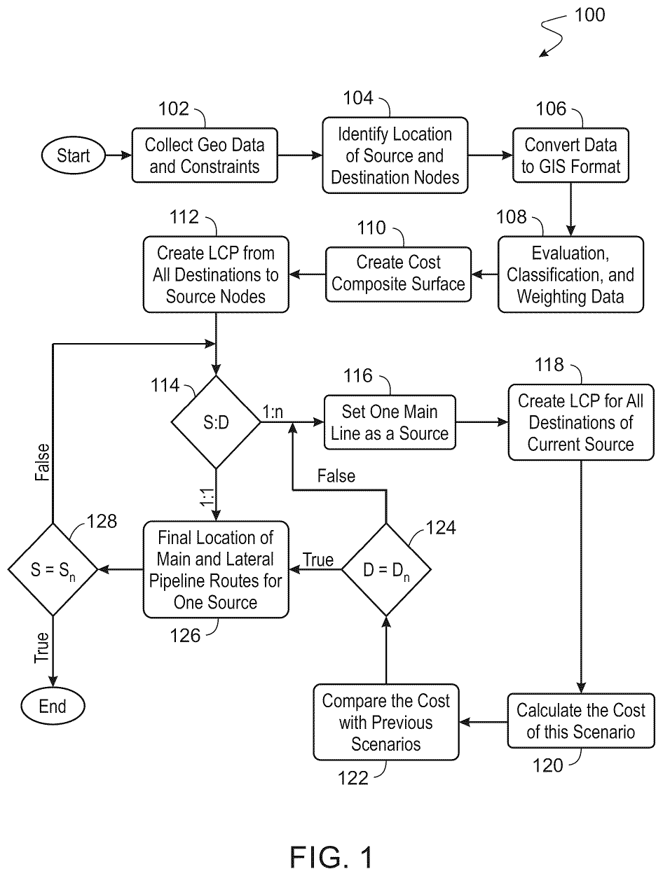

FIG. 1 shows a workflow 100 that enables a GIS-based determination of optimal routes for subsea pipelines. In examples, geophysical data and predetermined constraints are used to determine locations of pipeline routes for unestablished subsea pipelines in a facilitated manner. The workflow 100 determines optimal routes for interconnected pipeline networks that include multi-source and multi-destination nodes based on quantifiable costs and risk assessment.

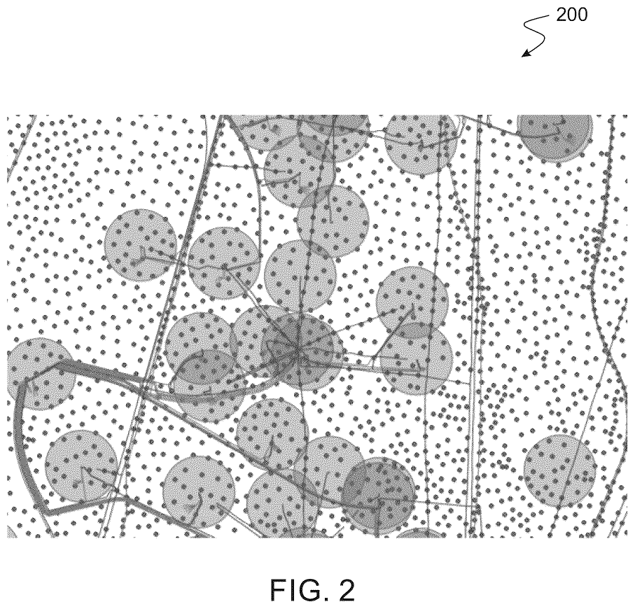

At block 102, geophysical data and constraints are obtained. In examples, the geophysical data and constraints are input data used to create a composite cost surface corresponding to a predetermined area, such as a project working area. This data includes bathymetric data, existing subsea facilities, and other geophysical data. Constraints include geohazard constraints, environmental constraints, and geotechnical constraints. In some embodiments, a geophysical survey is performed to collect geophysical data, such as bathymetric data. FIG. 2 shows geophysical data. In examples, the geophysical data includes existing pipeline and power cables of at least one existing offshore fields, existing platform locations of the same at least one offshore field, bathymetric data for the project area, environmental prohibited areas, average construction cost of pipeline per unit, average cost of crossing existing facilities, average cost of free span areas, the location of proposed wellheads and tie-in platforms that will be connected, and routes created by using manual of route selection. In examples, constraints are set by regulatory bodies (such as a Marine Department). Constraints set by regulatory bodies may be, for example, a maximum number of laterals that connect to a main line, the direction that a source should connect to a destination (i.e. north, south, east, west), and the minimum crossing angle to an existing pipeline. Additional constraints include existing infrastructure and facilities such as existing platforms, pipelines, power cables. These constraints can be determined, for example, by high level surveys or satellite imagery. In examples, constraints include environmental constraints that indicate environmentally prohibited areas that should be avoided. The environmental constraints are defined by environmental departments or environmental regulatory bodies.

Referring again to FIG. 1, at block 104, the location of source nodes and destination nodes in the predetermined area are identified. In examples, the source nodes and destination nodes are locations of offshore wellheads and tie-in platforms in a subsea pipeline network.

At block 106, the input data, source node locations, and destination node locations are converted into a GIS data format by using GIS Software such as Esri ArcGIS Pro. Accordingly, the input data and nodes of the subsea pipeline network are ready for GIS analysis. In examples, the GIS file format is a standard for encoding geographical information into a computer file, as a specialized type of file format for use in geographic information systems (GIS) and other geospatial applications. In examples, the input data and nodes include existing pipelines and power cables of the offshore field, existing platform locations of the offshore field, bathymetric data for the project area, and environmental prohibited areas. These data are converted into Shape files as a standard GIS format type.

In examples, the GIS data is used to create a model of the network. For example, the model is created, tested, and includes more than 30 GIS processes. In some embodiments, the model is a cell-based model. Each cell of the model represents a location and is associated with at least one value. The model is created by evaluating the value associated with each cell and modifying or retaining the value based on a predetermined series of rules. In examples, the value associated with each cell is determined on a cell-by-cell basis, where calculations for each cell use the value of the respective cell, the manipulation that is being applied, and other cell locations to include in the calculations.

At block 108, the input data is evaluated, classified, and weighted. In examples, a cost surface is created that is a raster surface that identifies the cost of traveling through each cell. In a cost surface, or cost grid, the value in each cell is the cost that a particular activity or object would be for that cell. In examples, the value can also be an indexed value based on costliness. Costs can be measured monetarily, by an amount of time, or in other measures. A cost surface includes the cost of reaching certain cells from one or more source cells.

In examples, the converted data of a cost surface is classified and weighted according to a real cost estimation and according to the analysis parameters. The cost surface is created by processing the criteria that affects the cost of each cell by using spatial analysis GIS tools. The analysis parameters are the variables that can be set by model users and can affect the cost of each cell in a cost surface. For example, the construction cost of 1 m of a pipeline. For example, if the installation of 1 m of a pipeline will cost $1000, and the analysis cell size is set to 20 m. Therefore, crossing one cell of the surface will cost $20,000. In examples, a cost criteria is the cost of intersecting with a large pipeline (e.g., large diameter) is different from the cost of intersecting a relatively smaller pipeline.

At block 110, the cost composite surface is created. Using the GIS analysis tools, the composite cost surface can be created based on the weighted input data. The composite cost surface is a raster cost surface accumulated from multiple cost surfaces. Each criterion is used to create one cost surface. The cost surfaces are accumulated to obtain the composite cost surface.

At block 112, iterative least cost path generation is initiated, where least cost paths are created from destinations to source nodes. In examples, the least cost path is a cheapest route relative to cost units defined by a predetermined cost analysis. In a least cost path analysis, cost surfaces are created for each of the criteria in the overall composite cost surface. Varying factors could influence the cost, depending on the analysis. In examples, at least one least cost path is generated between each source node and destination node of the model iteratively as shown by blocks 114-128.

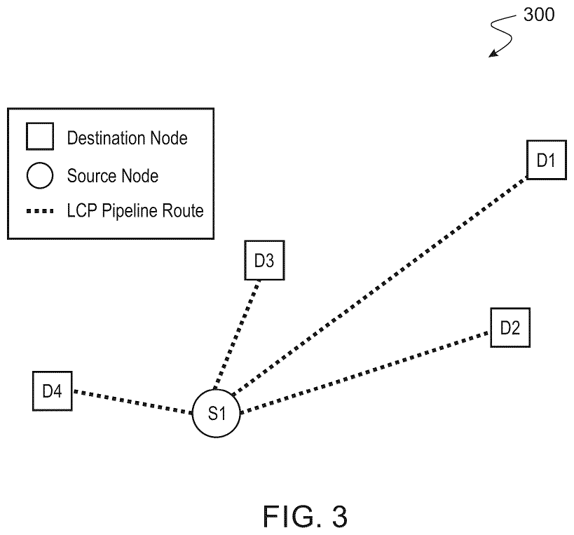

At block 114, it is determined if the current source node is associated with a single destination node or multiple destination nodes. If the current source node is associated with a single destination node, process flow continues to block 126. If the current source node is associated with multiple destination nodes, process flow continues to block 116. At block 116, the main line at the current source node is set as a source. At block 118, at least one least cost path is created between the current source node and each respective destination of the current source node. For each set of destinations that are connected to the same single source, different scenarios for identifying main and lateral pipeline routes are evaluated. In each scenario, one route will be selected as a main line. The selected main line will act as the source for the other destinations within this scenario. In some examples, a scenario refers to the particular least cost paths generated for the current source node and each respective destination of the current source node in an iteration. Using the GIS LCPA tools, the least cost routes can be created between the destination nodes and the source node based on the composite cost surface. In examples, the LCPA tools include a cost distance tool and a cost back link tool. For example, the least cost path is based, at least in part, on a cost distance calculated from the source node to the destination nodes using a path finding algorithm like Dijkstra's algorithm or A* algorithm. FIG. 3 shows least cost routes between the destinations and the source nodes based on the generated cost surface. The result of the analysis for an initial iteration will be one route from each destination to the source node.

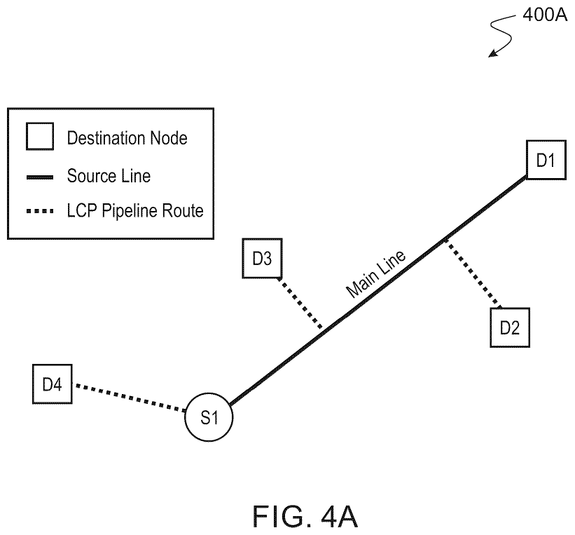

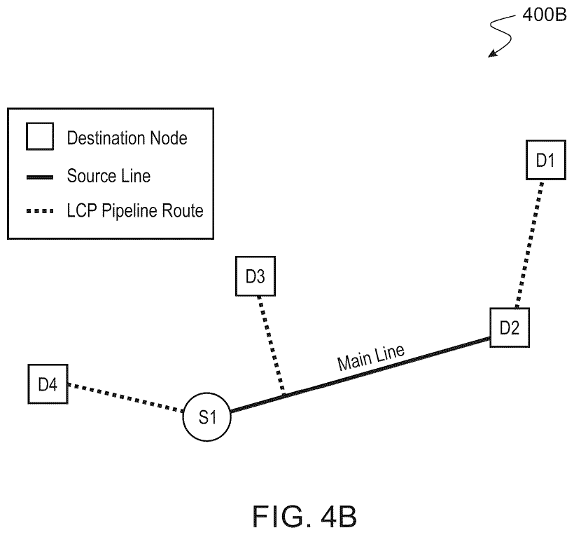

Referring again to FIG. 1, at block 120, a cost of the scenario is calculated. The LCPA will be performed for each scenario to determine the least cost route for each destination node within this scenario to any location on the selected main line of this scenario. At block 122, the cost of the current scenario is compared with the cost of previous scenarios. The cost of all scenarios will be calculated and compared to determine the least cost scenario for the whole set of the pipeline routes for a single source. FIG. 4A shows a first scenario 400A. FIG. 4B shows a second scenario 400B. In the scenarios 400A and 400B, a source node (Source 1 (S1)) and destination nodes (Destination 1 (D1), Destination 2 (D2), Destination 3 (D3), and Destination 4 (D4)) are shown. In the initial iteration, the least cost routes are created between the destination nodes and the source node with one route from each destination to a best source node based on the cost surfaces. Remaining scenarios are iteratively evaluated.

In the first scenario 400A of FIG. 4A, the main line connects Source 1 (S1) and Destination 1 (D1). A least cost path is shown between Source 1 (S1) and Destination 4 (D4). Additionally, least cost paths are shown between the main line and Destination 3 (D3), and the main line and Destination 2 (D2). In the second scenario 400B of FIG. 4B, the main line connects Source 1 (S1) and Destination 2 (D2). A least cost path is shown between Source 1 (S1) and Destination 4 (D4). Additionally, a least cost path is shown between the main line and Destination 3 (D3). A least cost path is shown between the Destination 1 (D1) and Destination 2 (D2). In examples, scenario 400B represents a final output scenario associated with a least cost main and lateral pipeline routes between source nodes and destination nodes of the pipeline network.

Referring again to FIG. 1 at block 114, if each single source is connected only to a single destination, there is a 1:1 relationship between source and destination, which means one scenario exists as the least cost path. Accordingly, the single cost is computed and process flow continues to block 126 where a final location of main and lateral pipeline routes for one source are determined.

On the other hand, if each single source is connected to multiple destinations, it will be a 1:n relationship between source and destinations, which means different scenarios exist, any of which can be the least cost path. In these scenarios, each destination can connect directly to a source or can connect indirectly as a lateral to a pipeline (main line) that connects between a source and another destination. Each respective scenario is iteratively evaluated to calculate total cost for each scenario through the blocks from 116-122. The total number of scenarios for each source will be equal to the total number of destinations connected to this source. At block 124, a check is performed to determine if the last destination D=Dₙ, is reached. If the last destination has been reached, the iterative looping evaluation ends. If not, the looping will cause evaluation of the next destination. At block 128, a check is performed to determine if the last source S=Sₙ is reached. If the last source is reached, the iterative looping evaluation ends. If not, the looping will cause evaluation of the next source.

Accordingly, each respective source node is evaluated and a least cost path analysis is performed for each scenario to determine a least cost route for each respective destination node within this scenario to any location on the selected main line of this scenario. The cost of the scenarios is calculated and compared to determine the least cost scenario for the whole set of the pipeline routes for a single source. The final output scenario will include the least cost main and lateral pipeline routes between source nodes and destination nodes of the pipeline network. The final output scenario will be associated with a lowest total cost of the scenarios. For each source, scenarios are iteratively evaluated to find the least cost scenario for the routes connected to this source. The resulting least cost scenario for the sources are combined to form a least cost solution for the entire network of sources and destinations. In examples, the number of scenarios for each source node is equal to the number of destinations connected to the respective source in addition to an initial scenario.

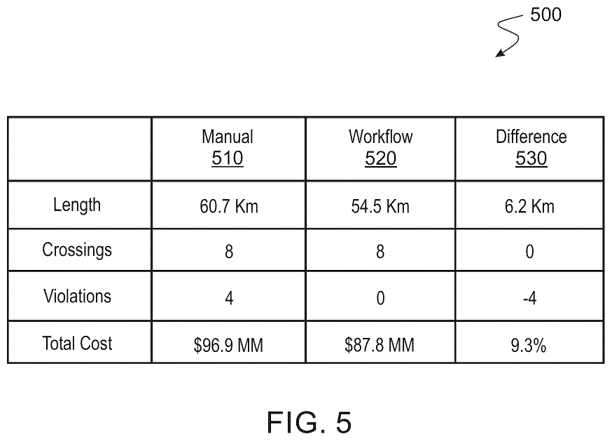

FIG. 5 shows metrics associated with proposed subsea routes. Metrics associated with a manual pipeline route is shown at column 510. Metrics associated with a pipeline route generated as described by FIGS. 1-4B are shown at column 520. A difference between column 510 and column 520 is shown at column 530. In examples, pipeline route generated as described by FIGS. 1-4B is modeled using geophysics software, such as Esri ArcGIS Pro Model Builder. As shown in chart 500, an estimated cost reduction increased 10% when compared to a traditional, manual technique.

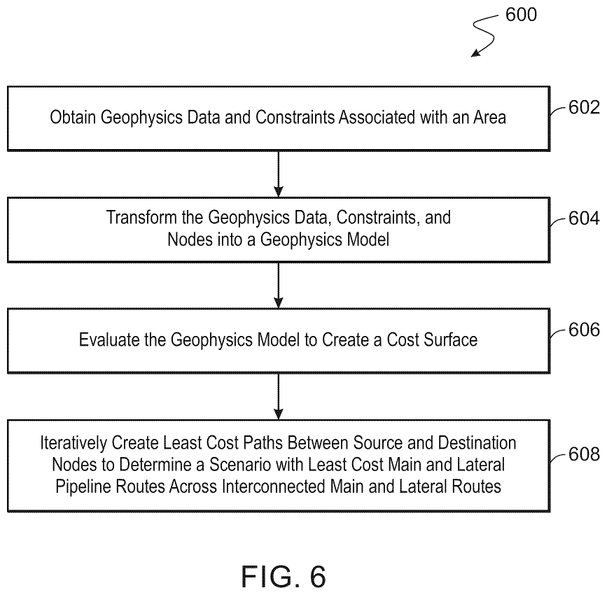

FIG. 6 is a process flow diagram of a process 600 that enables GIS-based determination of optimal routes for subsea pipelines.

At block 602, geophysics data and constraints associated with an area are obtained. In examples, geophysical data includes bathymetric data, existing subsea facilities, existing pipeline and power cables of at least one existing offshore field, existing platform locations of the same at least one offshore field, bathymetric data for the project area, environmental prohibited areas, average construction cost of pipeline per unit, average cost of crossing existing facilities, average cost of free span areas, the location of proposed wellheads and tie-in platforms that will be connected, and routes created by using manual of route selection. In examples, constraints include a maximum number of laterals that connect to a main line, the direction that a source should connect to a destination (i.e. north, south, east, west), the minimum crossing angle to an existing pipeline, existing platforms, pipelines, power cables, environmentally prohibited areas, or any combinations thereof.

At block 604, the geophysics data and constraints are transformed into a geophysics information system format. In some embodiments, the geophysics data, constraints, source node locations, and destination node locations, are converted into a GIS data format by using GIS Software. In some embodiments, the geophysics data, constraints, source node locations, and destination node locations, are converted into a gridded or cell-based geophysical model.

At block 606, the transformed geophysics data is evaluated to create a cost surface. In examples, a cost surface is created that is a raster surface that identifies the cost of traveling through each cell of a cell-based geophysical model.

At block 608, least cost paths are iteratively created between source and destination nodes to determine a scenario with least cost main and lateral pipeline routes across interconnected main and lateral routes. In examples, the scenario with least cost main and lateral pipeline routes across interconnected main and lateral routes is a final output scenario. Accordingly, the cost of the scenarios is calculated and compared to determine the least cost scenario for the whole set of the pipeline routes for a single source. The final output scenario is associated with the least cost main and lateral pipeline routes between source nodes and destination nodes of the pipeline network. Accordingly, the final output scenario is associated with a lowest total cost of the scenarios. In examples, the final output scenario represents a proposed pipeline network that minimizes the construction cost of new subsea pipelines by including pipeline routes associated with a least cost, and also minimizes the construction risk of accidental pipeline leakage that may cause negative production and negative environmental impacts.

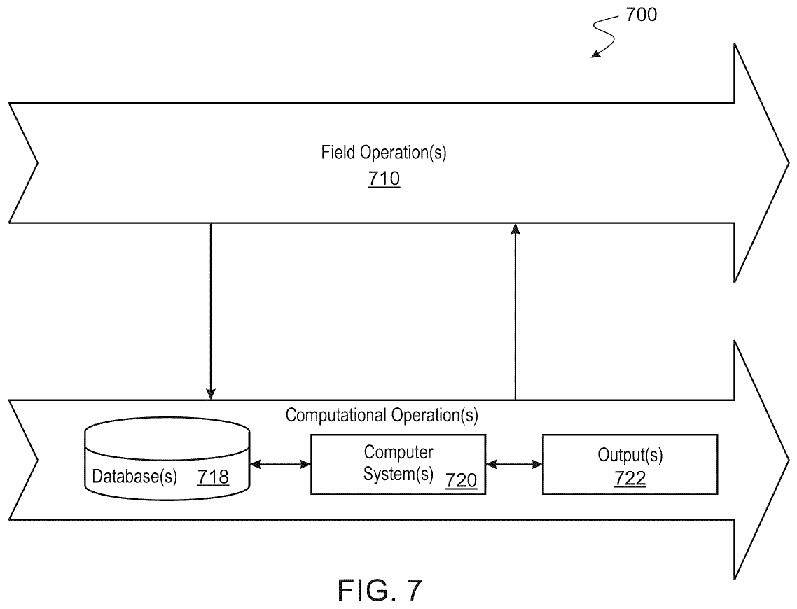

FIG. 7 illustrates hydrocarbon production operations 700 that include both one or more field operations 710 and one or more computational operations 712, which exchange information and control exploration for the production of hydrocarbons. In some implementations, outputs of techniques of the present disclosure can be performed before, during, or in combination with the hydrocarbon production operations 700, specifically, for example, either as field operations 710 or computational operations 712, or both.

Examples of field operations 710 include forming/drilling a wellbore, hydraulic fracturing, producing through the wellbore, injecting fluids (such as water) through the wellbore, to name a few. In some implementations, methods of the present disclosure can trigger or control the field operations 710. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 710 and responsively triggering the field operations 710 including, for example, generating plans and signals that provide feedback to and control physical components of the field operations 710. Alternatively or in addition, the field operations 710 can trigger the methods of the present disclosure. For example, implementing physical components (including, for example, hardware, such as sensors) deployed in the field operations 710 can generate plans and signals that can be provided as input or feedback (or both) to the methods of the present disclosure.

Examples of computational operations 712 include one or more computer systems 720 that include one or more processors and computer-readable media (e.g., non-transitory computer-readable media) operatively coupled to the one or more processors to execute computer operations to perform the methods of the present disclosure. The computational operations 712 can be implemented using one or more databases 718, which store data received from the field operations 710 and/or generated internally within the computational operations 712 (e.g., by implementing the methods of the present disclosure) or both. For example, the one or more computer systems 720 process inputs from the field operations 710 to assess conditions in the physical world, the outputs of which are stored in the databases 718. For example, seismic sensors of the field operations 710 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 712 where they are stored in the databases 718 and analyzed by the one or more computer systems 720.

In some implementations, one or more outputs 722 generated by the one or more computer systems 720 can be provided as feedback/input to the field operations 710 (either as direct input or stored in the databases 718). The field operations 710 can use the feedback/input to control physical components used to perform the field operations 710 in the real world.

For example, the computational operations 712 can process the seismic data to generate three-dimensional (3D) maps of the subsurface formation. The computational operations 712 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 712 to process new information about the formation and control the drilling to adjust to the observed conditions in real-time.

The one or more computer systems 720 can update the 3D maps of the subsurface formation as information from one exploration well is received and the computational operations 712 can adjust the location of the next exploration well based on the updated 3D maps. Similarly, the data received from production operations can be used by the computational operations 712 to control components of the production operations. For example, production well and pipeline data can be analyzed to predict slugging in pipelines leading to a refinery and the computational operations 712 can control machine operated valves upstream of the refinery to reduce the likelihood of plant disruptions that run the risk of taking the plant offline.

In some implementations of the computational operations 712, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

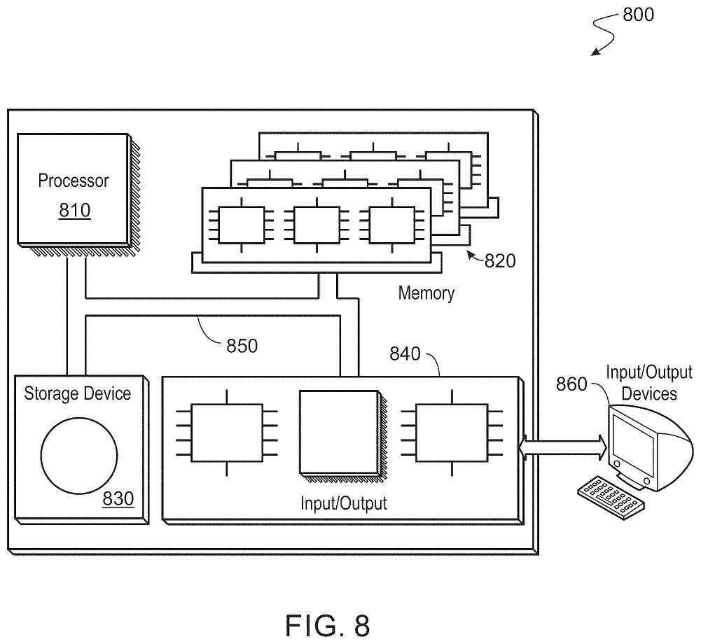

FIG. 8 is a schematic illustration of an example controller 800 (or control system) for that enables GIS-based determination of optimal routes for subsea pipelines. For example, the controller 800 may be operable according to the workflow 100 of FIG. 1 or the process 600 of FIG. 6. In some embodiments, the controller 800 is the same as or similar to the computer systems 720 of FIG. 7. The controller 800 is intended to include various forms of digital computers, such as printed circuit boards (PCB), processors, digital circuitry, or otherwise parts of a system for supply chain alert management. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 800 includes a processor 810, a memory 820, a storage device 830, and an input/output interface 840 communicatively coupled with input/output devices 860 (for example, displays, keyboards, measurement devices, sensors, valves, pumps). Each of the components 810, 820, 830, and 840 are interconnected using a system bus 850. The processor 810 is capable of processing instructions for execution within the controller 800. The processor may be designed using any of a number of architectures. For example, the processor 810 may be a CISC (Complex Instruction Set Computers) processor, a RISC (Reduced Instruction Set Computer) processor, or a MISC (Minimal Instruction Set Computer) processor.

In one implementation, the processor 810 is a single-threaded processor. In another implementation, the processor 810 is a multi-threaded processor. The processor 810 is capable of processing instructions stored in the memory 820 or on the storage device 830 to display graphical information for a user interface on the input/output interface 840.

The memory 820 stores information within the controller 800. In one implementation, the memory 820 is a computer-readable medium. In one implementation, the memory 820 is a volatile memory unit. In another implementation, the memory 820 is a nonvolatile memory unit.

The storage device 830 is capable of providing mass storage for the controller 800. In one implementation, the storage device 830 is a computer-readable medium. In various different implementations, the storage device 830 may be a floppy disk device, a hard disk device, an optical disk device, or a tape device.

The input/output interface 840 provides input/output operations for the controller 800. In one implementation, the input/output devices 860 includes a keyboard and/or pointing device. In another implementation, the input/output devices 860 includes a display unit for displaying graphical user interfaces.

There can be any number of controllers 800 associated with, or external to, a computer system containing controller 800, with each controller 800 communicating over a network. Further, the terms “client,” “user,” and other appropriate terminology can be used interchangeably, as appropriate, without departing from the scope of the present disclosure. Moreover, the present disclosure contemplates that many users can use one controller 800 and one user can use multiple controllers 800.

### Embodiments

According to some non-limiting embodiments or examples, provided is a computer-implemented method that enables GIS-based determination of optimal routes for subsea pipelines, including: obtaining, using at least one hardware processor, geophysics data and constraints associated with an area; transforming, using the at least one hardware processor, the geophysics data and constraints, source nodes, and destination nodes into a cell-based geophysics model; evaluating, using the at least one hardware processor, the cell-based geophysics model to create a composite cost surface corresponding to the area; and creating, using the at least one hardware processor, least cost paths iteratively between source nodes and destination nodes to determine a scenario with least cost main routes and least cost lateral pipeline routes across interconnected main routes and lateral routes in the cell-based geophysics model.

According to some non-limiting embodiments or examples, provided is an apparatus including a non-transitory, computer readable, storage medium that stores instructions that, when executed by at least one processor, cause the at least one processor to perform operations including: obtaining geophysics data and constraints associated with an area; transforming the geophysics data and constraints, source nodes, and destination nodes into a cell-based geophysics model; evaluating the cell-based geophysics model to create a composite cost surface corresponding to the area; and creating least cost paths iteratively between source nodes and destination nodes to determine a scenario with least cost main routes and least cost lateral pipeline routes across interconnected main routes and lateral routes in the cell-based geophysics model.

According to some non-limiting embodiments or examples, provided is a system, including: one or more memory modules; one or more hardware processors communicably coupled to the one or more memory modules, the one or more hardware processors configured to execute instructions stored on the one or more memory models to perform operations including: obtaining geophysics data and constraints associated with an area; transforming the geophysics data and constraints, source nodes, and destination nodes into a cell-based geophysics model; evaluating the cell-based geophysics model to create a composite cost surface corresponding to the area; and creating least cost paths iteratively between source nodes and destination nodes to determine a scenario with least cost main routes and least cost lateral pipeline routes across interconnected main routes and lateral routes in the cell-based geophysics model.

Further non-limiting aspects or embodiments are set forth in the following numbered embodiments:
Embodiment 1: A computer-implemented method that enables GIS-based determination of optimal routes for subsea pipelines, including: obtaining, using at least one hardware processor, geophysics data and constraints associated with an area; transforming, using the at least one hardware processor, the geophysics data and constraints, source nodes, and destination nodes into a cell-based geophysics model;
evaluating, using the at least one hardware processor, the cell-based geophysics model to create a composite cost surface corresponding to the area; and creating, using the at least one hardware processor, least cost paths iteratively between source nodes and destination nodes to determine a scenario with least cost main routes and least cost lateral pipeline routes across interconnected main routes and lateral routes in the cell-based geophysics model.
Embodiment 2: The computer implemented method of any of the preceding embodiments, wherein the cost surface is based on real weighting values for each cost criteria applied to the cell-based geophysics model.
Embodiment 3: The computer implemented method of any of the preceding embodiments, wherein the geophysics data includes existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.
Embodiment 4: The computer implemented method of any of the preceding embodiments, wherein the constraints are regulations established by regulatory bodies.
Embodiment 5: The computer implemented method of any of the preceding embodiments, wherein the least cost path is a cheapest route relative to cost units defined by a predetermined cost analysis.
Embodiment 6: The computer implemented method of any of the preceding embodiments, wherein transforming the geophysics data and constraints, the source nodes, and the destination nodes into a cell-based geophysics model includes converting the geophysics data and constraints, source node locations, and destination node locations into a GIS data format.
Embodiment 7: The computer implemented method of any of the preceding embodiments, including constructing a pipeline network based on the determined scenario with the least cost main routes and the least cost lateral pipeline routes across interconnected main routes and lateral routes in the cell-based geophysics model.
Embodiment 8: An apparatus including a non-transitory, computer readable, storage medium that stores instructions that, when executed by at least one processor, cause the at least one processor to perform operations including: obtaining geophysics data and constraints associated with an area; transforming the geophysics data and constraints, source nodes, and destination nodes into a cell-based geophysics model; evaluating the cell-based geophysics model to create a composite cost surface corresponding to the area; and creating least cost paths iteratively between source nodes and destination nodes to determine a scenario with least cost main routes and least cost lateral pipeline routes across interconnected main routes and lateral routes in the cell-based geophysics model.
Embodiment 9: The apparatus of any of the preceding embodiments, wherein the cost surface is based on real weighting values for each cost criteria applied to the cell-based geophysics model.
Embodiment 10: The apparatus of any of the preceding embodiments, wherein the geophysics data includes existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.
Embodiment 11: The apparatus of any of the preceding embodiments, wherein the constraints are regulations established by regulatory bodies.
Embodiment 12: The apparatus of any of the preceding embodiments, wherein the least cost path is a cheapest route relative to cost units defined by a predetermined cost analysis.
Embodiment 13: The apparatus of any of the preceding embodiments, wherein transforming the geophysics data and constraints, the source nodes, and the destination nodes into a cell-based geophysics model includes converting the geophysics data and constraints, source node locations, and destination node locations into a GIS data format.
Embodiment 14: The apparatus of any of the preceding embodiments, including constructing a pipeline network based on the determined scenario with the least cost main routes and the least cost lateral pipeline routes across interconnected main routes and lateral routes in the cell-based geophysics model.
Embodiment 15: A system, including: one or more memory modules; one or more hardware processors communicably coupled to the one or more memory modules, the one or more hardware processors configured to execute instructions stored on the one or more memory models to perform operations including: obtaining geophysics data and constraints associated with an area; transforming the geophysics data and constraints, source nodes, and destination nodes into a cell-based geophysics model; evaluating the cell-based geophysics model to create a composite cost surface corresponding to the area; and creating least cost paths iteratively between source nodes and destination nodes to determine a scenario with least cost main routes and least cost lateral pipeline routes across interconnected main routes and lateral routes in the cell-based geophysics model.
Embodiment 16: The system of any of the preceding embodiments, wherein the cost surface is based on real weighting values for each cost criteria applied to the cell-based geophysics model.
Embodiment 17: The system of any of the preceding embodiments, wherein the geophysics data includes existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.
Embodiment 18: The system of any of the preceding embodiments, wherein the constraints are regulations established by regulatory bodies.
Embodiment 19: The system of any of the preceding embodiments, wherein the least cost path is a cheapest route relative to cost units defined by a predetermined cost analysis.
Embodiment 20: The system of any of the preceding embodiments, wherein transforming the geophysics data and constraints, the source nodes, and the destination nodes into a cell-based geophysics model includes converting the geophysics data and constraints, source node locations, and destination node locations into a GIS data format.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

What is claimed is:

1. A computer-implemented method that enables GIS-based determination of optimal routes for subsea pipelines, comprising:
obtaining, using at least one hardware processor, geophysics data and constraints associated with an area;
transforming, using the at least one hardware processor, the geophysics data and constraints, source nodes, and destination nodes into a cell-based geophysics model;
evaluating, using the at least one hardware processor, the cell-based geophysics model to create a composite cost surface corresponding to the area; and
creating, using the at least one hardware processor, least cost paths iteratively between source nodes and destination nodes to determine a scenario with least cost main routes and least cost lateral pipeline routes across interconnected main routes and lateral routes in the cell-based geophysics model.

2. The computer implemented method of claim 1, wherein the cost surface is based on real weighting values for each cost criteria applied to the cell-based geophysics model.

3. The computer implemented method of claim 1, wherein the geophysics data comprises existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.

4. The computer implemented method of claim 1, wherein the constraints are regulations established by regulatory bodies.

5. The computer implemented method of claim 1, wherein the least cost path is a cheapest route relative to cost units defined by a predetermined cost analysis.

6. The computer implemented method of claim 1, wherein transforming the geophysics data and constraints, the source nodes, and the destination nodes into a cell-based geophysics model comprises converting the geophysics data and constraints, source node locations, and destination node locations into a GIS data format.

7. The computer implemented method of claim 1, comprising constructing a pipeline network based on the determined scenario with the least cost main routes and the least cost lateral pipeline routes across interconnected main routes and lateral routes in the cell-based geophysics model.

8. An apparatus comprising a non-transitory, computer readable, storage medium that stores instructions that, when executed by at least one processor, cause the at least one processor to perform operations comprising:
obtaining geophysics data and constraints associated with an area;
transforming the geophysics data and constraints, source nodes, and destination nodes into a cell-based geophysics model;
evaluating the cell-based geophysics model to create a composite cost surface corresponding to the area; and
creating least cost paths iteratively between source nodes and destination nodes to determine a scenario with least cost main routes and least cost lateral pipeline routes across interconnected main routes and lateral routes in the cell-based geophysics model.

9. The apparatus of claim 8, wherein the cost surface is based on real weighting values for each cost criteria applied to the cell-based geophysics model.

10. The apparatus of claim 8, wherein the geophysics data comprises existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.

11. The apparatus of claim 8, wherein the constraints are regulations established by regulatory bodies.

12. The apparatus of claim 8, wherein the least cost path is a cheapest route relative to cost units defined by a predetermined cost analysis.

13. The apparatus of claim 8, wherein transforming the geophysics data and constraints, the source nodes, and the destination nodes into a cell-based geophysics model comprises converting the geophysics data and constraints, source node locations, and destination node locations into a GIS data format.

14. The apparatus of claim 8, comprising constructing a pipeline network based on the determined scenario with the least cost main routes and the least cost lateral pipeline routes across interconnected main routes and lateral routes in the cell-based geophysics model.

15. A system, comprising:
one or more memory modules;
one or more hardware processors communicably coupled to the one or more memory modules, the one or more hardware processors configured to execute instructions stored on the one or more memory models to perform operations comprising:
obtaining geophysics data and constraints associated with an area;
transforming the geophysics data and constraints, source nodes, and destination nodes into a cell-based geophysics model;
evaluating the cell-based geophysics model to create a composite cost surface corresponding to the area; and
in creating least cost paths iteratively between source nodes and destination nodes to determine a scenario with least cost main routes and least cost lateral pipeline routes across interconnected main routes and lateral routes in the cell-based geophysics model.

16. The system of claim 15, wherein the cost surface is based on real weighting values for each cost criteria applied to the cell-based geophysics model.

17. The system of claim 15, wherein the geophysics data comprises existing pipeline and power cables of at least one existing offshore fields, existing platform locations of the at least one offshore field, bathymetric data for the at least one offshore field, environmental prohibited areas, average construction cost of pipeline per unit, average cost of crossing existing facilities, average cost of free span areas, locations of proposed wellheads and tie-in platforms, and routes created by manual of route selection.

18. The system of claim 15, wherein the constraints are regulations established by regulatory bodies.

19. The system of claim 15, wherein the least cost path is a cheapest route relative to cost units defined by a predetermined cost analysis.

20. The system of claim 15, wherein transforming the geophysics data and constraints, the source nodes, and the destination nodes into a cell-based geophysics model comprises converting the geophysics data and constraints, source node locations, and destination node locations into a GIS data format.
